(19) United States
(12) Patent Application Publication
(10) Pub. No.: US 2008/0054358 A1
(43) Pub. Date: Mar. 6, 2008

(54) Thin film transistor and method of manufacturing thin film and thin film transistor

(75) Inventors: Masakazu OKADA, Kyoto-shi (JP); Yuya HIRAO, Ritto-shi (JP)

Correspondence Address: BRINKS HOFER GILSON & LIONE, P.O. BOX 10395, CHICAGO, IL, 60610, US

(73) Assignee: KONICA MINOLTA HOLDINGS, INC.

(21) Appl. No.: 11/894,826

(22) Filed: Aug. 22, 2007

(30) Foreign Application Priority Data
Aug. 29, 2006 (JP) JP2006-231825
Jul. 3, 2007 (JP) JP2007-174957

(51) Int. Cl. H01L 29/786; H01L 21/31; H01L 21/3205

(52) U.S. Cl. 257/347; 438/585; 438/787; 257/E29.273; 257/E21.24; 257/E21.294

(57) ABSTRACT

A method of manufacturing a thin film including the steps of: providing a film manufacturing apparatus including a first discharge electrode, a second discharge electrode placed opposed to the first discharge electrode and a high frequency power source, which supplies high frequency power between the first discharge electrode and a second discharge electrode; placing a substrate on which a conductive line pattern has been formed on the second discharge electrode; applying the high frequency power from the high frequency power supply while generating plasma by using discharged gas under an atmospheric pressure or a near-atmospheric pressure; and forming a thin film on the substrate, wherein a space ratio (W/L) of a line width W (W>0) of the conductive line pattern to a spatial distance L between the first discharge electrode and the substrate is set not more than 0.1.

This application is based on Japanese Patent Application No. 2006-231825 filed on Aug. 29, 2006, and No. 2007-174957 filed on Jul. 3, 2007, in Japanese Patent Office, the entire content of which is hereby incorporated by reference.

### TECHNICAL FIELD

This invention relates to a thin film transistor and a method of manufacturing a thin film and a thin film transistor.

### BACKGROUND

As information terminals have become popular, the need for flat panel displays for s computers has increased. And further, as information network has progressed, the information which has been distributed through a paper sheet based medium in a past has come to the situation where it is electrically processed and distributed in many occasions. Accordingly, the need for electronic paper or digital paper, which is thin and light medium and capable of being easily carried as a mobile display medium, has increased.

In general, in a flat type display apparatus, a display medium is structured by an element using LCD (Liquid Crystal Display), organic electro-luminescence or electrophoresis. In the case of such display media, in order to secure the uniformity of the screen intensity and a rewrite-speed of the screen, the technology of using active drive element structured by thin film transistors (TFT) as image drive elements has become a main stream.

The TFT element is normally manufactured by sequentially forming a semiconductor thin film of a-Si (amorphous silicon) or p-Si (Poly-Silicon), and a metal thin film for a source, a drain and a gate on a glass substrate. In the manufacturing of a flat panel display, using TFT elements, in general, a photo-lithography process having high accuracy is needed in addition to a thin film forming process requiring vacuum equipment and high temperature processes. Accordingly, the load of equipment management and process control is very large. Further, as a trend of a larger size screen display in recent years becomes greater, the load of equipment management and process control has become further larger.

In recent years, research and development of an organic TFT element utilizing an organic semiconductor material is intensively progressed. (Refer to Unexamined Japanese Patent Application Publication No. H10-190001 and Magazine, Advanced Material, year 2002, volume 2, page 99 (Review)). Since, the organic semiconductor material is easy to process, the study of a TFT element for particularly driving image pixels in a liquid crystal display apparatus is intensively progressed.

In case of using the organic semiconductor material, there is a possibility that the manufacture of TFT element becomes easy. However, with respect to the obtained organic TFT element as a result, it becomes hard to fully satisfy the requirements, such as, an ON/OFF current ratio, leak current, stability and product life as the organic TET element. It is a problem to simplify the manufacturing process and at the same time to improve the characteristics and stability as an organic TFT element.

In order to solve the problems described above, Unexamined Japanese Patent Application Publication No. 2003-179234 discloses a manufacturing method for improving the characteristics of an organic TFT element and simplifying a manufacturing process by forming a gate insulation film of the organic TFT element by applying, for example, a plasma process under the atmospheric pressure environment.

Further, Unexamined Japanese Patent Application Publication No. 2003-179234 discloses a manufacturing method for improving the characteristics of an organic TFT element and simplifying a manufacturing process by forming a gate insulation film of the organic TFT element by deploying a semiconductor layer so as to be sandwiched by two insulation films formed using a plasma process under the ascosporic pressure.

However, when forming a thin film on the substrate on which conductive pattern having a line pattern has been formed, by applying a plasma process under the atmospheric pressure disclosed by Unexamined Japanese Patent Application Publications Nos. 2003-179234 and 2004-207331, there was sometimes a case that unevenness of the film thickness and variation of the film quality occurred, and a required optimum thin film was not obtained.

### SUMMARY

It is, therefore, an object of the present invention is to provide a thin film transistor and a method of manufacturing a thin film and a thin film transistor having superior characteristics, the method being capable of stably forming a thin film having a uniform thickness on a substrate on which conductive line pattern has been formed. In view of forgoing, one embodiment according to one aspect of the present invention is a method of manufacturing a thin film, the method comprising the steps of:

placing a substrate on a second discharge electrode arranged facing a first discharge electrode, a conductive line pattern having been formed on the substrate; and

forming the thin film on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,

wherein a ratio W/L of a width W of the conductive line pattern to a special distance L between the first discharge electrode and the substrate is equal to or less than 0.1.

According to another aspect of the present invention, another embodiment is a method of manufacturing a thin film transistor which has, on a substrate, at least a gate electrode, a gate insulation layer, a source electrode, a drain electrode and a semiconductor layer, the method comprising the steps of:

forming a conductive line pattern as the gate electrode on the substrate;

placing the substrate having the conductive line pattern on a second discharge electrode arranged facing a first discharge electrode; and

forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,

wherein a ratio W/L of a width W of the conductive line pattern to a special distance L between the first discharge electrode and the substrate is equal to or less than 0.1.

According to another aspect of the present invention, another embodiment is a thin film transistor which has, on a substrate, at least a gate electrode, a gate insulation layer, a source electrode, a drain electrode and a semiconductor layer, the thin film transistor manufactured by a method comprising the steps of:

forming a conductive line pattern as the gate electrode on the substrate;

placing the substrate having the conductive line pattern on a second discharge electrode arranged facing a first discharge electrode; and

forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,

wherein a ratio W/L of a width W of the conductive line pattern to a special distance L between the first discharge electrode and the substrate is equal to or less than 0.1.

According to another aspect of the present invention, another embodiment is a method of manufacturing a gate insulation layer of a thin film transistor which has, on a substrate, a gate electrode, a gate insulation layer, a source electrode, a drain electrode and a semiconductor layer, the method comprising the steps of:

placing the substrate having only the gate electrode on a second discharge electrode arranged facing a first discharge electrode; and

forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,

wherein a ratio W/L of a width W of the conductive line pattern to a special distance L between the first discharge electrode and the substrate is equal to or less than 0.1.

According to another aspect of the present invention, another embodiment is a thin film transistor which has, on a substrate, a gate electrode, a gate insulation layer, a source electrode, a drain electrode and a semiconductor layer, the thin film transistor manufactured by a method comprising the steps of:

placing the substrate having only the gate electrode on a second discharge electrode arranged facing a first discharge electrode; and

forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,

wherein a ratio W/L of a width W of the conductive line pattern to a special distance L between the first discharge electrode and the substrate is equal to or less than 0.1.

According to another aspect of the present invention, another embodiment is a method of manufacturing an organic thin film transistor which has, on a substrate, a source electrode, a drain electrode, an organic semiconductor portion between the source electrode and the drain electrode, a gate electrode, and an insulation film between the organic semiconductor portion and the gate electrode, the method comprising the step of:

forming the insulation film by plasma processing between two discharge electrodes under an atmospheric pressure or a near-atmospheric pressure,

wherein a ratio W/L of a width W of the gate electrode to a special distance L between any one of the discharge electrodes and the substrate is equal to or less than 0.1.

### BRIEF DESCRIPTION OF THE DRAWINGS

FIG. 1 is an explanatory drawing illustrating an example of a film manufacturing apparatus 50 for manufacturing a thin film pertaining to the present invention.

FIGS. 2a, 2b, 2c and 2d are explanatory drawings illustrating a process for manufacturing films on the substrate on which conductive line pattern has been formed.

FIGS. 3a, 3b, 3c and 3d are sectional views illustrating a cross sectional view of the embodiment of a method of manufacturing a thin film transistor pertaining to the present invention.

FIGS. 4a, 4b, 4c and 4d are plan views illustrating an embodiment of a method of the manufacturing a thin film transistor of the present invention.

FIGS. 5a and 5b are explanatory drawings illustrating the directions of a first discharging electrode 4 and a conductive line pattern when manufacturing a thin film.

FIG. 6 is a drawing illustrating a graph for showing the relationship between the space ratio of a thin film manufactured by an embodiment 1 and a surface roughness.

FIG. 7 is a drawing illustrating a graph for showing the relationship between a space ratio of the organic TFT element manufactured by an embodiment 2 and mobility.

### DETAILED DESCRIPTION OF THE PREFERRED EMBODIMENT

The present invention will be described in detail by referring to embodiments of the present invention. However, the present invention is not limited to these embodiments.

A thin film is manufactured by a plasma film manufacturing process under the atmospheric pressure in this invention. The plasma film manufacturing process under the atmospheric pressure will be described hereinafter.

The plasma film manufacturing process under the atmospheric pressure means a process for forming a thin film on a substrate by causing discharge and exciting discharge gas to form plasma under the atmospheric pressure or the pressure close to the atmospheric pressure. The method thereof is disclosed in Unexamined Japanese Patent Publications Nos. 2003-179234, 2004-207331, H11-133205, 2000-185362, H11-61406, 2000-147209 and 2000-121804. This is named, an atmospheric pressure plasma method.

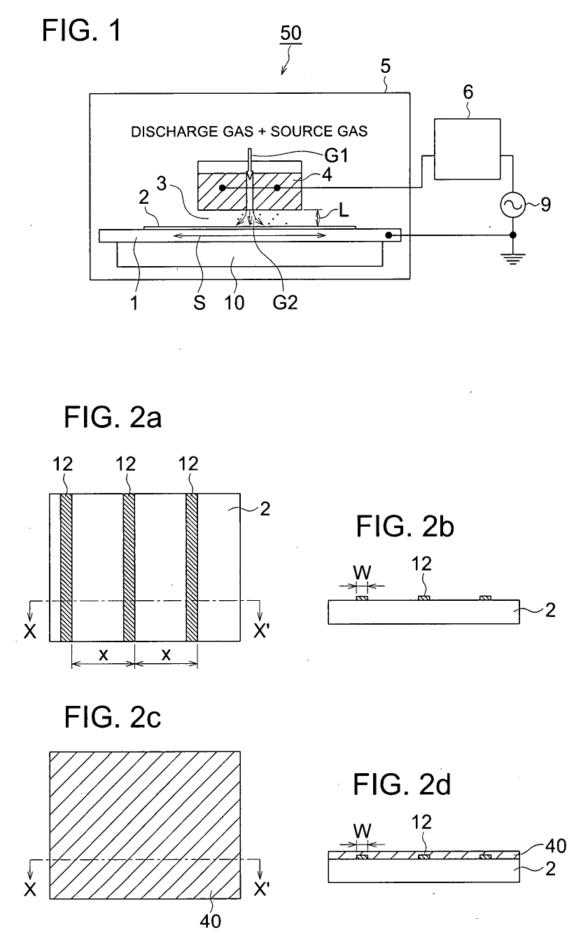

FIG. 1 is an explanatory drawing illustrating an example of a film manufacturing apparatus 50 for manufacturing thin film pertaining to the present invention.

The film manufacturing apparatus 50 is configured by a high frequency power source 9, a discharge adjustment apparatus 6 and a film manufacturing apparatus case 5.

The first end of the high frequency power source 9 is connected to a first discharge electrode 4 in the film manufacturing apparatus case 5 through the discharge adjustment apparatus 6. A second discharge electrode 1 is disposed against the first discharge electrode 4 in the film manufacturing apparatus case 5. The second discharge electrode 1 is connected to the second end of the high frequency power source 9, which is grounded.

The high frequency power source 9 supplies power for causing discharge between the first discharge electrode 4 and the second discharge electrode 1. The voltage for starting discharge is, for example, equal to or more than 500V. The discharge adjustment apparatus 6 is provided for impedance matching between the high frequency power supply 9 and the first discharge electrode 4. In the discharge adjustment apparatus 6 (not shown), for example, a tuning coil and a tuning condenser are connected in parallel to adjust them to be an optimum impedance. The discharge power is appropriate within the range where glow-discharge keeps occurring, the range being set, for example, 100 W-800 W.

The method for supplying high frequency power between the first discharge electrode 4 and the second discharge electrode 1 is not limited to an embodiment where the power is supplied from the high frequency power source 9. It may also be possible to conduct discharge by separately connecting respective high frequency power sources with the first discharge electrode 4 and the second discharge electrode 1 and utilizing the voltage difference between the ground and respective electrodes.

A space, which is indicated by an arrow G1, as illustrated in FIG. 1 is provided in the first discharge electrode 4, into which gas is injected from the upper portion of the first discharge electrode 4 to the direction shown by the arrow G1. The gas to be injected is a mixed gas, into which a discharge gas for generating plasma, a source gas corresponding to the kind of thin film to be formed and a reactant gas for promoting reaction of the source gas have been mixed. The mixed gas injected from the upper portion of the first discharge electrode 4 diffuses into the space having a space length L, which is equal to the distance between the lower surface of the first discharge electrode 4 and the substrate 2, along with the arrows G2. When applying high frequency power between the first discharge electrode 4 and the second discharge electrode 1, a plasma space 3 occurs. The substrate 2 is a substrate to be processed to manufacture a thin film thereon, and the substrate 2 is placed on the second discharge electrode 1. The spatial distance L between the lower surface of the first discharge electrode 4 and the substrate 2 can be changed by adjusting the height of the first discharge electrode 4 by using an adjusting member (not shown). The spatial distance L is generally adjusted not less than 0.5 mm and not more than 1.5 mm from the viewpoint of maintaining uniform discharge.

In this embodiment, an embodiment including a single first discharge electrode 4 will be described. However, an embodiment including a plurality of first discharge electrodes 4, where gas is injected into the space formed between the plurality of first discharge electrodes 4 may be possible.

The film manufacturing apparatus 50 can generate plasma by starting discharges under the atmospheric pressure or the pressure close thereto. The atmospheric pressure or the pressure close thereto denotes pressure of about 20 kPa-110 kPa, preferably about 93 kPa-104 kPa.

The second discharge electrode 1 is fixed onto the support table 10, which is capable of being reciprocally moved along an arrow S of FIG. 1 by a driving member (not shown in FIG. 1). When forming the film, the support table 10 is reciprocally moved to move the second electrode 1 and the substrate 2 on the support table 10 so that the surface of the substrate 2 is uniformly disposed to plasma to form a uniform thin film on an entire surface of the substrate 2.

In this embodiment, an example including the second discharge electrode 1 having a flat surface as shown in FIG. 1 has been described. However, it is also possible to use the second discharge electrode 1 having, for example, a cylindrical shape to form a thin film while winding the substrate 2 composed of a flexible resin sheet around the second discharge electrode 1 having a cylindrical shape.

Next, the process for forming a film onto the substrate having a conductive line pattern by using the film formation apparatus 50, which is illustrated in FIG. 1.

FIGS. 2a and 2c are plan views illustrating the substrate 2 viewed from the upper surface side. FIGS. 2b and 2d are cross sectional views taken along the line X-X′ illustrating the substrate.

FIGS. 2a and 2b are drawings illustrating the substrate 2, on which conductive line patters 12 having a line width W with equal interval x have been formed. FIGS. 2c and 2d are drawings illustrating situations where a thin film 40 has been formed on the upper surface of the substrate 2 after the film manufacturing process has completed.

In this invention, a glass substrate having a resistibility of not less than 10⁻⁸ Ω·cm, which is called an insulator, in general, or a flexible resin sheet can be used as the substrate 2. Or there can be used a substrate having a conductive pattern thereon, on the surface of which an insulation material having a resistibility of not less than 10⁻⁸ Ω·cm is coated such that the thickness of coating layer is not less than 0.1 mm to give insulation to the surface of the substrate.

The conductive line pattern 12 is formed by material having a resistibility of not more than 10⁻² Ω·cm by using a direct patterning technique, such as a photo-lithography process, IJ method and a screen print method, onto the substrate 2.

The substrate 2 on which the conductive line pattern 12 has been formed is placed onto the second discharge electrode 1 in the film manufacturing apparatus 50.

Next, a surface roughness Ra of the thin film 40 will be described.

When forming a thin film 40 onto the substrate 2 by using the film manufacturing apparatus 50, in case where the line width W of the conductive line pattern 12 on the substrate 2 becomes larger with respect to the spatial distance L between the lower surface of the first discharge electrode 4 and the substrate 2, the disorder of the discharge tends to occur and there comes a situation where a thin film formation having a uniform film quality cannot be achieved. Accordingly, the surface roughness Ra of the formed thin film becomes large. Suppose that the width of the conductive line pattern is to be W, and the spatial distance between the lower surface of the first discharge electrode 4 and the substrate 2 of the film manufacturing apparatus 50 is to be L, the thin film surface roughness Ra depends on the space ratio (W/L). The space ratio (W/L) to obtain a uniform film thickness needs to be not more than 0.1, which will be described by using an embodiment. In order to realize that the space ratio (W/L) to be not more than 0.1, the line width W of the conductive line pattern 12 may be designed corresponding to the spatial distance L or the spatial distance may be adjusted corresponding to the line width W.

In an example where the second discharge electrode 1 having a flat surface is placed so as to be parallel with the first discharge element 4, the distance between them is always the same, which is the spatial distance L as shown in FIG. 1. However, for example, in the case where forming a thin film by winding a substrate 2 composed of a resin sheet onto the second discharge electrode 1 having a cylindrical shape, the distance between the lower surface of the first discharge electrode 4 and the surface of the second substrate 2, which is located at the most closest position to the lower surface of the first discharge electrode 4 is arranged to be the spatial distance L.

Next, a method for manufacturing a thin film transistor by employing the method for manufacturing a thin film of the present invention will be described.

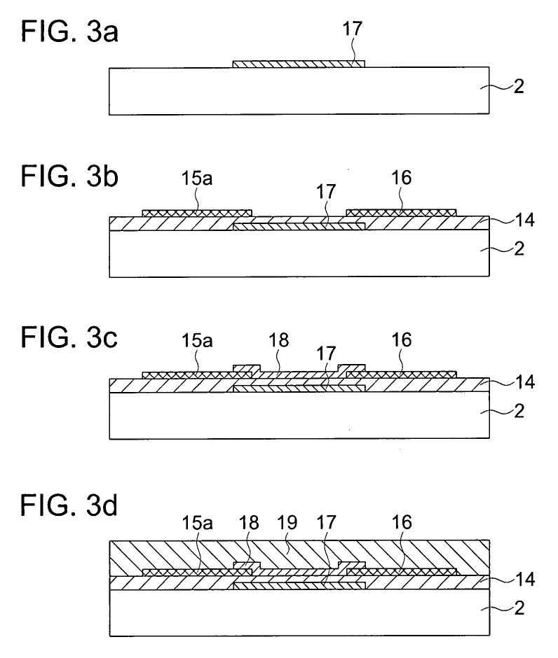

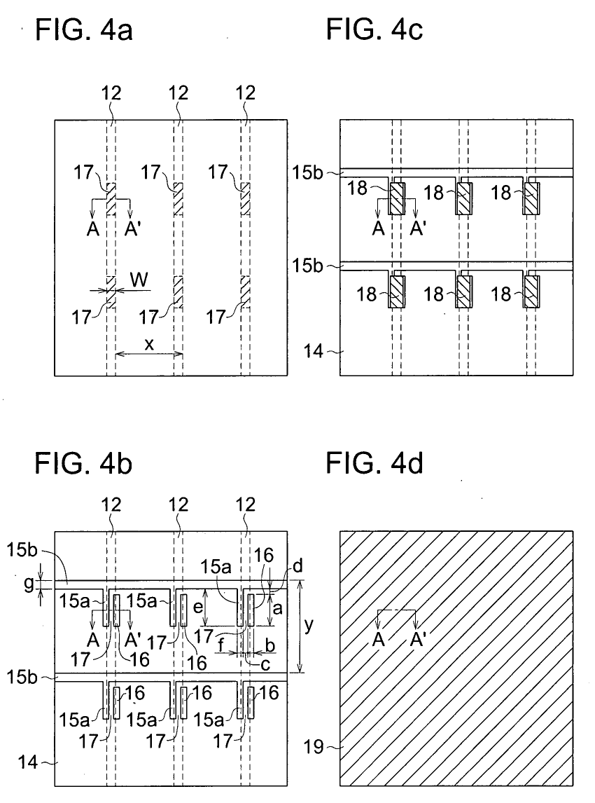

FIGS. 3a, 3b 3c and 3d are cross sectional views illustrating an embodiment of the method of manufacturing a thin film transistor pertaining to the present invention. FIGS. 4a, 4b, 4c and 4d are plan views explaining a manufacturing process of forming thin film transistors of 2×3 on the substrate 2 by employing the method of the manufacturing a thin film transistor of the present invention. FIGS. 3a-3d are cross-sectional views taken along the line A-A′ of FIGS. 4a-4d illustrating the channel section of the thin film transistor.

Processes S0-S4 for a bottom gate type thin film transistor will be described as an example of a method for manufacturing the thin film transistor pertaining to the present invention will be described. S0: a process for forming a gate electrode 17, S1: a process for forming a gate insulation layer 14, S2: a process for manufacturing a source electrode and a drain electrode, S3: a process for manufacturing a film of semiconductor layer 18, and S4: a process for manufacturing a film of a semiconductor protective layer.

Respective processes will be described hereinafter.

S0: A process for forming the gate electrode 17

The material of the substrate 2 will not be limited. For example, glass or a flexible resin sheet may be used as the substrate 2. After having coated photo-resist onto the substrate 2 on which a conductive thin film has been formed, exposure through a photo-mask and a development process is conducted. The conductive line pattern 12 as illustrated in FIG. 3a and FIG. 4a is formed on the substrate 2. The portion indicated by a shadow area 17 in FIG. 4a is a portion where a semiconductor layer 18 is formed on an upper layer of the line pattern 12, which is to function as a gate electrode 17. The portion of the conductive line pattern 12 other than the gate electrode 17 functions as a wiring pattern section for supplying control voltage to the gate electrode 17.

In FIG. 4a, following symbols will indicate the dimensions of respective sections.

W: a line width of conductive line pattern 12.

x: an interval between conductive line patterns 12.

The line width of conductive line pattern 12 “W” is arranged so that the space ratio (W/L) becomes not more than 0.1 as described in FIG. 2a.

S1: A process for forming the gate insulation layer 14

Next, the gate insulation layer 14 is formed on the entire surface of the substrate 2.

The film manufacturing apparatus 50 forms the gate insulation layer 14 by a plasma manufacturing film under the atmospheric pressure or the pressure closed thereto.

In this embodiment, an example for manufacturing a SiO₂ film, which is an insulation film, as the gate insulation layer 14 will be described. With respect to the material of the SiO₂, TEOS (Tetraethoxysilane) is used. A gas formed by bubbling TEOS with the same kind of discharge gas as a discharge gas and by vaporizing thereof is used as a source gas. Argon is used as the discharge gas in this embodiment. Further, for example, O₂ is used as a reactant gas.

Source gas, discharge gas and reactant gas are not limited to ones described above, and should be determined corresponding to the kind of the film to be formed.

For example, rare gas, such as, Argon, Helium, Neon and Xenon can be used as discharge gas. However, from the cost reduction point of view, Argon is preferable. Further, instead of the rare gas described above, Oxygen, Nitrogen, Carbon dioxide and Hydrogen may be used. However, Nitrogen is preferably used from the cost reduction point of view.

Regarding the source gas for forming a gate insulation layer 14, for example, Organometallic chemical compound, Halogen chemical compound and Metal-Hydrogen chemical compound can be sued. From handling point of view, since the risk of explosion is low, organometallic compound is preferably used. Particularly, the organometallic compound including oxygen not less than 1 in a molecule preferably used.

With respect to the organometallic compound, which may be used to form an insulation layer, for example, Tetraethlsilane, Tetramethylsilane, Tetraethoxysilane (TEOS), Tetramethoxysilane (TMOS), Tetramethoxysilan (TMS), Trimethylefluososilane (4MS), Hexamethyldisiloxane (HMDSO) may be used.

S2: A process for manufacturing a source electrode and a drain electrode

As illustrated in FIGS. 3b and 4b, a source electrode 15a and a drain electrode 16 are formed on a gate insulation layer 14 by an inkjet method. Symbol 15b denotes a wiring pattern section for functioning as a source line and the portion extended from the source line 15b functions as the source electrode.

In FIG. 4b, the following symbols indicate dimensions of respective sections.

a: Length of the drain electrode 16

b: Width of the drain electrode 16

c: Distance between the drain electrode 16 and the source electrode 15a

d: Distance between the source line 15b and the drain electrode 16

e: Length of the portion extended from the source line 15b of the source electrode 15a

f: Width of the source electrode 15a

g: Width of the source line 15b

y: Interval between the source lines 15b

S3: Process for manufacturing a film of semiconductor layer

As illustrated in FIGS. 3c and 4c, the semiconductor layer 18 will be formed in a channel section.

In this invention, the semiconductor material is not limited to special one. There can be employed materials from inorganic semiconductor, such as Amorphous Silicon, to organic semiconductor, such as Pentacene. With respect to the method for forming a film, it is not limited to an inkjet method, a coating method and an evaporation method.

S4: A process for manufacturing a film of a semiconductor protective layer

As illustrated in FIGS. 3d and 4d, a semiconductor protective layer 19 is formed onto the entire surface of the substrate 2. With respect to the method of manufacturing a film of the semiconductor protective layer 19, evaporation methods, such as an atmospheric plasma method and a CVD method, and a coating method, such as a spin-coat method can be utilized. In the case of using the evaporation method, SiO₂ may be used as a semiconductor protective layer 19. In the case of using the spin-coat method, Optoma PC-403, which is a Photosensitive Acrylate material, may be used as the semiconductor protective layer 19. The method for manufacturing a film of the semiconductor protective layer 19 and the material are not limited to those described above.

After that, a contact hole for contacting the drain electrode 16 is made in the semiconductor protective layer 19, and a pixel electrode for contacting with the contact hole is formed by the coating type ITO to compete the organic TFT.

### EXAMPLES

Examples to confirm effects of the present invention will be described hereinafter. However, the present invention is not limited to these examples.

### Example 1

In this example, the conductive line patterns as illustrated in FIGS. 2a and 2b have been structured with equal intervals on a glass substrate having a size of 100 mm×100 mm on which AlNd film having a thickness of 125 nm has been formed. The size of glass substrate is 100 mm×100 mm and the interval of the conductive line patterns 12 is designed to be 350 μm.

A thin film of SiO₂ has been formed onto the substrate 2 on which the conductive line pattern 12 has been formed, by using the film manufacturing apparatus 50, which has been explained by referring to FIG. 1. Experimental conditions are as following.

In the cases where the spatial distance L between the lower surface of the first discharge electrode 4 and the substrate 2 are 0.5 mm, 1 mm and 1.5 mm, SiO₂ thin films have been formed on the substrate 2 with the line width of the SiO₂ thin film varied corresponding to the space ratio (W/L). And the surface roughness for respective cases has been measured. The discharge power between the first discharge electrode 4 and the second discharge electrode 1 was 500 W, and the atmospheric pressure was 100 kPa.

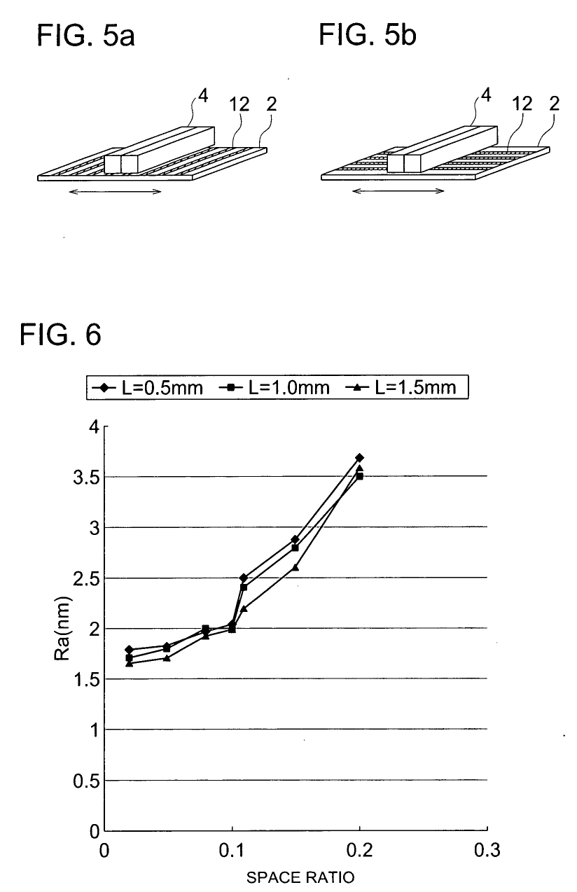

FIGS. 5a and 5b are explanatory drawings for illustrating drawings for explaining the directions of a first discharging electrode 4 and the conductive line pattern 12 when manufacturing the thin film. As illustrated in FIGS. 5a and 5b, the direction of the conductive line patter 12 has been changed and the film formation has been carried out. The arrow direction is the direction, along which the substrate 1 is moved when forming the film.

TEOS (Tetraethoxysilane) has been used as a material of SiO₂ film, and the gas into which TEOS has been bubbled with the same kind of gas as the discharge gas and evaporated has been used as the source gas. The discharge gas was Argon and the reactant gas was O₂. With regard to the gas flow amount, the source gas is 5 (L/min.), the discharge gas is 20 (L/min.) and the reactant gas is 0.1 (L/min.).

[Experimental Results]

FIG. 6 is a drawing illustrating the experimental results. FIG. 6 illustrates a graph showing the relationship between the space ratio and the surfaced roughness Ra.

According to FIG. 6, in any case where the spatial distance L is set at 0.5, 1 mm or 1.5 mm, when the space ratio (W/L) is not more than 0.1, the surface roughness Ra is no more than 2 nm. However, in case when the space ratio is more than 0.1, the surface roughness Ra rapidly increases. Experiment has been conducted after having changed the direction of the conductive line pattern as shown in FIGS. 5a and 5b. However the experimental result was the same. Thus, irrespective to the direction of the conductive line pattern 12, when the space ration is set not more than 0.1, the surface roughness can be controlled not more than 2 nm. Further, in case where the space ratio is set not more than 0.05, the surface roughness can be controlled within a range of 1.6 nm-1.8 nm, was a better result obtained.

### Example 2

A bottom gate type thin film transistor has been formed on the substrate 2, the number of the bottom gate type thin film transistors on the substrate 2 being total 100, which comes from 10×10 on the substrate 2, by using the film manufacturing apparatus 50.

In the cases where the spatial distance L between the lower surface of the first discharge electrode 4 and the substrate 2 are set 0.5 mm, 1 mm and 1.5 mm, the relationship between the space ratio and the mobility has been obtained by using the substrate 2 where the line width W has been varied corresponding to the space ratio (W/L).

The atmospheric pressure was 100 kPa when forming the film by the plasma method.

[Manufacturing of Thin Film Transistor]

The substrate 2 is a substrate having a size of 100 mm×100 mm, Polyethersulfone substrate of Sumitomo Bakelite Co., Ltd.

Since the film transistor has been formed on the process S0-S4 of the embodiment 1, which has been explained by referring to FIG. 3, the explanation of the common points will be omitted here.

S0: A process for forming a gate electrode 17

By coating photo-resist onto the substrate 2 on which a conductive thin film has been formed and conducting exposure through a photo-mask, the conductive line pattern 12 has been formed. The interval “x” of the formed line patterns 12 formed of the conductive thin film is 350 μm. In case where the spatial distance L is 0.5 mm, 1 mm and 1.5 mm, there has been made and test the substrate 2, on which the line width W is varied so that the space ratio (W/L) became seven values of 0.02, 0.05, 0.08, 0.1, 0.11, 0.15 and 0.2.

S1: A process for forming a gate insulation layer 14

The film manufacturing apparatus 50 forms the gate insulation layer 14 structured by SiO₂.

With regard to the source gas of SiO₂, a gas, into which TEOS (Tetraethoxysilane) has been bubbled with the same kind of gas as the discharge gas and evaporated, has been used. The discharge gas was Argon and the reactant gas was O₂. With respect to the gas flow amount, the source gas is 5 (L/min.), the discharge gas is 20 (L/min.) and the reactant gas is 0.1 (L/min.). The discharge power between the first discharge electrode 4 and the second discharge electrode 1 is 500 W.

S2: A process for forming a source electrode and a drain electrode

The electrode illustrated in FIG. 4b has been formed by a spattering method using gold.

The dimensions of respective sections of this embodiment illustrated in FIG. 4b will be described below.

Length a of the drain electrode 16: 150 μm

Width of the drain electrode 16: 50 μm

Distance c between the drain electrode 16 and the source electrode 15a: 10 μm

Distance d between the source line 15b and the drain electrode 16: 5 μm

Length e of the part extended from a source line 15b of the source electrode 15a: 155 μm

Width f of the source electrode 15b: 50 μm

Width g of the source line 15b: 50 μm

Interval between the source lines 15b: 350 μm

S3: A process for manufacturing a semiconductor layer 18

Film is formed by a vacuum evaporation method of Pentacene.

S4: A process for manufacturing a semiconductor layer 19

The film manufacturing apparatus 50 forms the semiconductor protective layer 19 structured by SiO₂.

With regard to the source gas of SiO₂, a gas, into which TEOS (Tetraethoxysilane) has been bubbled with the same kind of gas as the discharge gas and evaporated, has been used. The discharge gas was Argon and the reactant gas was O₂. With regard to the gas flow amount, the source gas is 5 (L/min.), the discharge gas is 20 (L/min.) and the reactant gas is 0.1 (L/min.). The discharge power between the first discharge electrode 4 and the second discharge electrode 1 is 500 W.

After that, a contact hole for contacting the drain electrode 16 was made in the semiconductor protective layer 19 and a pixel electrode for contacting with the contact hole was formed by the coating type ITO to complete the organic TFT.

[Experimental Results]

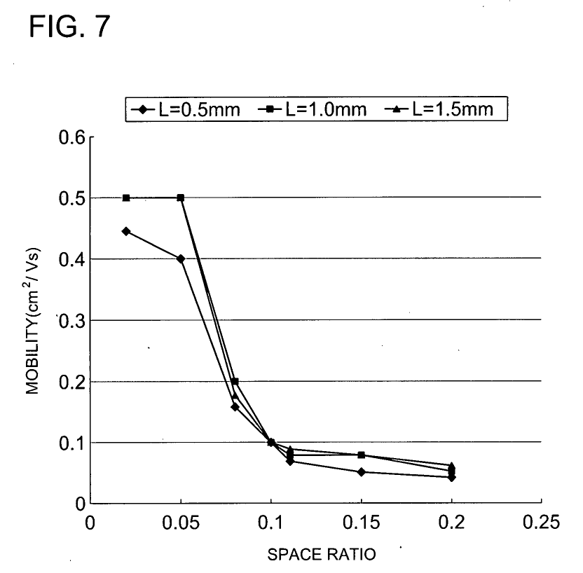

The experimental results are shown in FIG. 7. FIG. 7 is a drawing illustrating a graph for showing the relationship between a space ratio and mobility. In this experiment, thin film transistors have been formed on twenty-one substrates 2 by varying the condition of the spatial distance L. Of hundred organic TFT elements of each substrate 2, twenty-four organic TFT elements have been randomly selected, and the mobility of respective elements have been evaluated.

According to FIG. 7, in any case where the spatial distances L are 0.5 mm, 1 mm and 1.5 mm, when the space ratio is not more than 0.1, the mobility is not less that 0.1 (cm₂/Vs) and the thin film transistors have superior characteristics. However, in case when the space ratio (W/L) becomes more than 0.1, the value of mobility rapidly decreases. Further, in case when the space ratio is set not more than 0.05, mobility becomes not less than 0.4, which is a further preferable result obtained.

The reason is thought to be as follows. When the surface roughness of the gate insulation layer 14 becomes large, there is increased the number of starting points, from which the film grows when forming a film of a semiconductor material, accordingly, crystal size (grain size) of the semiconductor material becomes small. Thus, it is thought that when the crystal size becomes small, since the boundary surface (particle surface) between crystal particles, which interferes carriers to move, increase, the value of the mobility of a formed thin film transistor decreases.

As described above, since when the space ratio (W/L) is set not more than 0.1, the surface roughness of the gate insulating layer 14 can be controlled small, and the thin film transistor having high mobility can be manufactured.

A method of manufacturing a thin film of the present invention can be adopted by the manufacturing process of the semiconductor integrated circuit and by the process where forming conductive line pattern on a substrate, such as a printed circuit board (PCB) or a flexible printed circuit board (FPC), where a conductive layer and an insulation layer are alternatively layered.

As described above, according to the present invention, by setting the ratio of the line width W of a conductive line pattern on the substrate on which a thin film is formed to a spatial distance L not more than 0.1, there can be provided a method for stably manufacturing a thin film having a uniform thickness even on a substrate having a conductive line pattern, a method of manufacturing a thin film transistor having a superior characteristic and a thin film transistor.

What is claimed is:

1. A method of manufacturing a thin film, the method comprising the steps of:
placing a substrate on a second discharge electrode arranged facing a first discharge electrode, a conductive line pattern having been formed on the substrate; and
forming the thin film on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,
wherein a ratio W/L of a width W of the conductive line pattern to a special distance L between the first discharge electrode and the substrate is equal to or less than 0.1.

2. The method of claim 1, wherein the ratio W/L of the width W of the conductive line pattern to the special distance L between the first discharge electrode and the substrate is equal to or less than 0.05.

3. The method of claim 1, wherein the near-atmosphere pressure is from 20 kPa to 110 kPa.

4. A method of manufacturing a thin film transistor which has, on a substrate, at least a gate electrode, a gate insulation layer, a source electrode, a drain electrode and a semiconductor layer, the method comprising the steps of:
forming a conductive line pattern as the gate electrode on the substrate;
placing the substrate having the conductive line pattern on a second discharge electrode arranged facing a first discharge electrode; and
forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,
wherein a ratio W/L of a width W of the conductive line pattern to a special distance L between the first discharge electrode and the substrate is equal to or less than 0.1.

5. The method of claim 4, wherein the gate insulation layer includes SiO₂.

6. A thin film transistor which has, on a substrate, at least a gate electrode, a gate insulation layer, a source electrode, a drain electrode and a semiconductor layer, the thin film transistor manufactured by a method comprising the steps of:
forming a conductive line pattern as the gate electrode on the substrate;
placing the substrate having the conductive line pattern on a second discharge electrode arranged facing a first discharge electrode; and
forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,
wherein a ratio W/L of a width W of the conductive line pattern to a special distance L between the first discharge electrode and the substrate is equal to or less than 0.1.

7. A method of manufacturing a gate insulation layer of a thin film transistor which has, on a substrate, a gate electrode, a gate insulation layer, a source electrode, a drain electrode and a semiconductor layer, the method comprising the steps of:
placing the substrate having only the gate electrode on a second discharge electrode arranged facing a first discharge electrode; and
forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,
wherein a ratio W/L of a width W of the conductive line pattern to a special distance L between the first discharge electrode and the substrate is equal to or less than 0.1.

8. The method of claim 7, wherein the gate insulation layer includes SiO₂.

9. The method of claim 7, wherein the near-atmosphere pressure is from 20 kPa to 110 kPa.

10. A thin film transistor which has, on a substrate, a gate electrode, a gate insulation layer, a source electrode, a drain electrode and a semiconductor layer, the thin film transistor manufactured by a method comprising the steps of:
placing the substrate having only the gate electrode on a second discharge electrode arranged facing a first discharge electrode; and
forming the gate insulation layer on the substrate by supplying a high frequency power from a high frequency power supply while supplying a discharge gas to generate plasma under an atmospheric pressure or a near-atmospheric pressure, the high frequency power supply being for supplying a high frequency power between the first discharge electrode and the second discharge electrode,
wherein a ratio W/L of a width W of the conductive line pattern to a special distance L between the first discharge electrode and the substrate is equal to or less than 0.1.

11. A method of manufacturing an organic thin film transistor which has, on a substrate, a source electrode, a drain electrode, an organic semiconductor portion between the source electrode and the drain electrode, a gate electrode, and an insulation film between the organic semiconductor portion and the gate electrode, the method comprising the step of:
forming the insulation film by plasma processing between two discharge electrodes under an atmospheric pressure or a near-atmospheric pressure,
wherein a ratio W/L of a width W of the gate electrode to a special distance L between any one of the discharge electrodes and the substrate is equal to or less than 0.1.

12. The method of claim 11, wherein the gate insulation layer includes SiO₂.

13. The method of claim 11, wherein the near-atmosphere pressure is from 20 kPa to 110 kPa.
